(19) United States
(12) Patent Application Publication
(10) Pub. No.: US 2026/0007040 A1
(43) Pub. Date: Jan. 1, 2026

(54) ELECTRONIC DEVICE AND DISPLAY APPARATUS

(71) Applicant: Samsung Display Co., Ltd., Yongin-si (KR)

(72) Inventors: Youngjoo Nam, Yongin-si (KR); Jooyoung Kim, Yongin-si (KR)

(73) Assignee: Samsung Display Co., Ltd., Yongin-si (KR)

(21) Appl. No.: 19/226,353

(22) Filed: Jun. 3, 2025

(30) Foreign Application Priority Data
Jul. 1, 2024 (KR) 10-2024-0086414

(51) Int. Cl. H10K 59/80; H10K 59/88; H10K 102/00

(52) U.S. Cl. CPC H10K 59/871; H10K 59/88; H10K 2102/311

(57) ABSTRACT

A display apparatus includes a display panel including a first surface including a display area, and a second surface different from the first surface, a protective member disposed on the second surface and directly contacting the display panel, a display controller including at least a portion of the display controller inserted into the protective member, and a connection member electrically connecting the display panel to the display controller.

### CROSS-REFERENCE TO RELATED APPLICATION(S)

This application claims priority to and the benefits of Korean Patent Application No. 10-2024-0086414 under 35 U.S.C. § 119, filed on Jul. 1, 2024, in the Korean Intellectual Property Office, the entire contents of which are incorporated herein by reference.

### BACKGROUND

### 1. Technical Field

One or more embodiments relate to an apparatus, and more, to an electronic device and a display apparatus.

### 2. Description of the Related Art

Mobile electronic devices are widely used. As well as miniaturized electronic devices such as mobile phones, tablet personal computers (PCs) have also recently become widely used as mobile electronic apparatuses.

To support various functions, for example, to provide a user with visual information, such as images, such mobile electronic devices include a display panel. Recently, as the parts configured to drive a display panel have been miniaturized, the proportion of the display panel in an electronic device has gradually increased and a structure that may bend to a preset angle with respect to a flat state is also under development.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

A display controller controlling a display panel may be disposed on the rear surface of the display panel. Because the display controller protrudes from the rear surface of the display panel, in case that an impact is applied from the outside, the display controller may come in contact with a housing and damage the display panel. One or more embodiments include an electronic device and a display apparatus capable of reduced damage to a display panel in case that an external impact is applied.

Additional aspects will be set forth in part in the description which follows and, in part, will be apparent from the description, or may be learned by practice of the presented embodiments of the disclosure.

According to one or more embodiments, a display apparatus may include a display panel including a first surface including a display area, and a second surface different from the first surface; a protective member disposed on the second surface of the display panel and directly contacting the display panel; a display controller including at least a portion of the display controller inserted into the protective member; and a connection member electrically connecting the display panel to the display controller.

The display panel may include a substrate, a display layer disposed on the substrate and disposed in the display area, and an encapsulation member disposed over the substrate and encapsulating the display layer.

The display apparatus may further include an optical functional layer disposed on the encapsulation member.

The display panel may further include an input-sensing layer disposed on the encapsulation member.

The display panel may further include a cover member disposed on the encapsulation member.

The protective member may include an embossed first layer, a porous second layer disposed on the embossed first layer, and a third layer including metal and disposed on the porous second layer.

At least a portion of the display controller may be disposed inside of the porous second layer.

The porous second layer may include an opening into which the display controller is received, and a roughness of the opening may be different from a roughness of another portion of the porous second layer.

The display apparatus may further include an inner housing disposed on a lateral surface of the display panel and surrounding the display controller.

The inner housing may electrically connect the display controller to the protective member.

The display apparatus may further include an adhesive member disposed between the protective member and the display controller.

The connection member may bend.

The protective member may include a first alignment mark in a portion on which the display controller is disposed, and the display controller may include a second alignment mark in a position corresponding to the first alignment mark.

An electronic device may be based on one of the above.

According to one or more embodiments, a display apparatus may include a display panel including a first surface including a display area, and a second surface different from the first surface; a display controller facing the second surface; a protective member disposed between the second surface and the display controller, wherein a thickness of a portion of the protective member where the display controller is disposed is different from a thickness of other portions of the protective member, and a connection member electrically connecting the display panel to the display controller.

The thickness of the portion of the protective member where the display controller is disposed may be less than the thickness of the other portions of the protective member.

The protective member may include a first layer contacting the second surface of the display panel, a second layer disposed on the first layer and including a first portion and a second portion having different thicknesses, and a third layer including metal and disposed on the second layer.

A roughness of a surface of the first portion facing the third layer including the metal may be different from a roughness of a surface of the second portion.

The third layer including the metal may be electrically connected to the display controller.

The display apparatus may further include an adhesive member disposed between the protective member and the display controller.

The protective member may include a first alignment mark in a portion on which the display controller is disposed, and the display controller may include a second alignment mark in a position corresponding to the first alignment mark.

An electronic device may include a display panel including a first surface including a display area, and a second surface different from the first surface; a protective member disposed on the second surface of the display panel and directly contacting the display panel;

a display controller including at least a portion of the display controller inserted into the protective member; and a connection member electrically connecting the display panel to the display controller.

The display panel may include: a substrate; a display layer disposed on the substrate and disposed in the display area; and an encapsulation member disposed over the substrate and encapsulating the display layer.

The protective member may include: an embossed first layer; a porous second layer disposed on the embossed first layer; and a third layer including metal and disposed on the porous second layer.

The connection member may bend.

The protective member includes a first alignment mark in a portion on which the display controller is disposed, and the display controller includes a second alignment mark in a position corresponding to the first alignment mark.

The electronic device may be at least one of televisions, notebook computers, monitors, advertisement boards, Internet of things (IoTs) device, portable electronic devices including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.

These and/or other aspects will become apparent and more readily appreciated from the following detailed description of the embodiments, the accompanying drawings, and claims.

These general and other aspects may be implemented by using a system, a method, a computer program, or a combination of a given system, method, and computer program.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of a portion of a display apparatus, taken along line II-II′ of FIG. 1;

FIG. 3 is a schematic cross-sectional view of a protective member and an enlarged view of region A of FIG. 2;

FIG. 4 is a schematic plan view of the display panel, the connection member, and the display controller shown in FIG. 2;

FIG. 5 is a schematic cross-sectional view of a portion of a display panel, taken along line V-V′ of FIG. 4;

FIG. 6 is a schematic diagram of an equivalent circuit of a sub-pixel circuit shown in FIG. 5;

FIGS. 7A and 7B are schematic views showing an order of disposing a display controller of a display apparatus on the rear surface of a display panel, according to an embodiment;

FIG. 8 is a schematic cross-sectional view of a portion of a display apparatus according to an embodiment;

FIG. 9 is a schematic backside view of a portion of a display apparatus according to an embodiment;

FIG. 10 is a schematic cross-sectional view of a portion of a display apparatus according to an embodiment;

FIG. 11 is a schematic cross-sectional view of a portion of a display apparatus according to an embodiment;

FIG. 12 is a schematic cross-sectional view of a portion of a display apparatus according to an embodiment;

FIG. 13 is a block diagram of an electronic device according to an embodiment; and

FIGS. 14 to 16 are schematic views of electronic devices according to various embodiments.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

As the disclosure allows for various changes and numerous embodiments, embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof may be omitted.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

As used herein, the singular forms, “a,” “an,” and “the” are intended to include the plural forms as well, unless the context clearly indicates otherwise.

It will be understood that the terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be further understood that, when a layer, region, or element is referred to as being “on” another layer, region, or element, it can be directly or indirectly on the other layer, region, or element. For example, intervening layers, regions, or elements may be present.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The X direction, the Y direction and the Z direction are not limited to three axes of the rectangular coordinate system, and may be interpreted in a broader sense. For example, the X direction, the Y direction and the Z direction may be perpendicular to one another, or may represent different orientations that are not perpendicular to one another.

wherein case that an embodiment may be implemented differently, a specific process order may be performed in the order different from the described order. As an example, two processes successively described may be simultaneously performed substantially and performed in the opposite order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

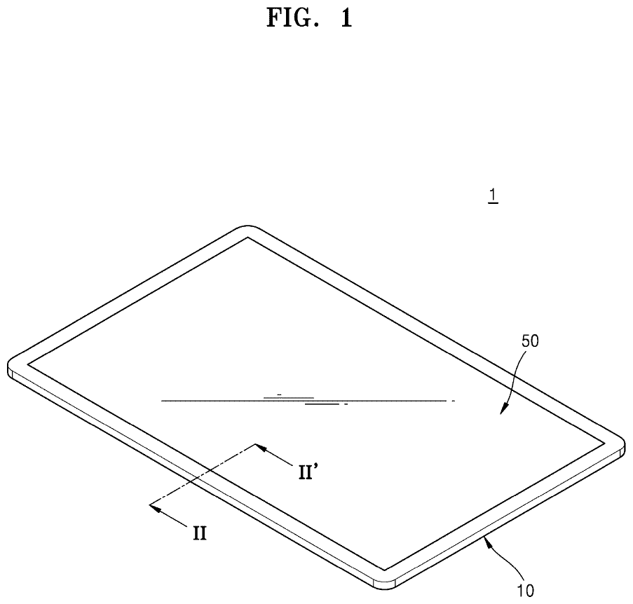

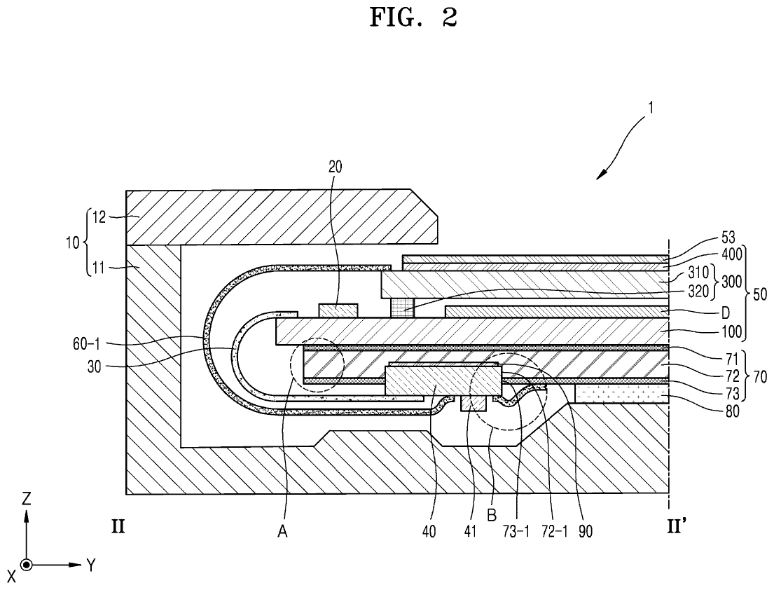

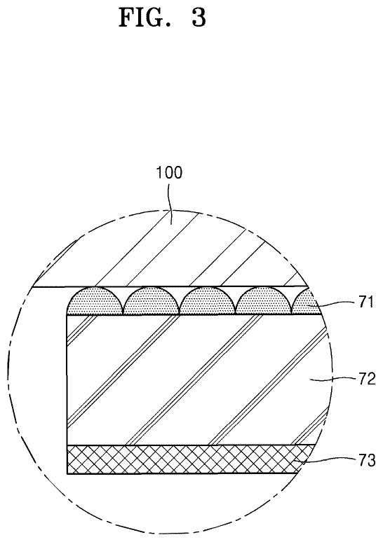

FIG. 1 is a schematic perspective view of a display apparatus according to an embodiment. FIG. 2 is a schematic cross-sectional view of a portion of the display apparatus, taken along line II-II′ of FIG. 1. FIG. 3 is a schematic cross-sectional view of a protective member and an enlarged view of a region A of FIG. 2.

Referring to FIGS. 1 to 3, the display apparatus 1 may include an apparatus for displaying moving images or still images and may be used as a display screen of various products including televisions, notebook computers, monitors, advertisement boards, Internet of things (IoTs) device as well as portable electronic devices including mobile phones, smartphones, tablet personal computers (PCs), mobile communication terminals, electronic organizers, electronic books, portable multimedia players (PMPs), navigations, and ultra mobile personal computers (UMPCs). The display apparatus 1 may be used in wearable devices including smartwatches, watchphones, glasses-type displays, and head-mounted displays (HMDs). In an embodiment, the display apparatus 1 may be used as a display screen in instrument panels for automobiles, center fascias for automobiles, or center information displays (CIDs) arranged (or disposed) on a dashboard, room mirror displays that replace side mirrors of automobiles, and displays of an entertainment system arranged on the backside of front seats for backseat passengers in automobiles.

The display apparatus 1 may include a housing 10, a display panel 50, an optical functional layer 53, a connection member 30, a protective member 70, display controllers 40 and 41, an inner housing 60-1, a first adhesive member 80, and a second adhesive member 90.

The display panel 50 may be configured to display (output) information processed by the display apparatus 1. As an example, the display panel 50 may display execution screen information of an application driven in the display apparatus 1, or user interface (UI) and graphic user interface (GUI) information corresponding to the execution screen information. The display panel 50 may include a display layer D and an input-sensing layer 400, wherein the display layer D displays images, and the input-sensing layer 400 senses a user's touch input. Accordingly, the display panel 50 may serve as one of input devices that provide an input interface between the display apparatus 1 and a user, and simultaneously, serve as one of output devices that provide an output interface between the display apparatus 1 and a user.

Hereinafter, although an organic light-emitting display apparatus is described as an example of the display apparatus 1 according to an embodiment, the display apparatus 1 is not limited thereto. In an embodiment, the display apparatus 1 of the disclosure may be an inorganic light-emitting display apparatus or a quantum-dot light-emitting display apparatus. As an example, an emission layer of a display element provided to the display apparatus 1 may include an organic material, an inorganic material, quantum dots, an organic material and quantum dots, or an inorganic material and quantum dots.

In an embodiment, the display panel 50 may be a flexible display panel which has flexibility and thus is readily bendable, foldable, or rollable. As an example, the display panel 50 may include a foldable display panel that is foldable and unfoldable, a curved display panel that has a curved display surface, a bended display panel in which a region except a display surface is bent, a rollable display panel that is rollable and unrollable, and a stretchable display panel that is stretchable. In an embodiment, the display panel 50 may be a rigid display panel that has rigidity and thus does not readily bend.

The display panel 50 may include a substrate 100, the display layer D disposed on the substrate 100, and an encapsulation member 300 that separates the display layer D from the outside. The encapsulation member 300 may include an encapsulation substrate 310 and a sealing member 320. The encapsulation substrate 310 may be disposed to face the substrate 100, and the sealing member 320 may be disposed between the substrate 100 and the encapsulation substrate 310. The sealing member 320 may be disposed to surround the outer side of the display layer D. The substrate 100, the sealing member 320, and the encapsulation substrate 310 form a space separated from the outside. Because the display layer D is disposed in the space, external oxygen, moisture, and the like may be prevented from penetrating the display layer D. The display panel 50 may include the input-sensing layer 400 disposed on the encapsulation member 300.

The housing 10 may form the appearance of the rear surface of the display apparatus 1. The housing 10 may include plastic, metal, or both plastic and metal. The display panel 50 may be received in the housing 10. The housing 10 may include a main housing 11 in which the display panel 50 is disposed, and a decorative housing 12 coupled or connected to the main housing 11. The decorative housing 12 may include an opaque material.

The optical functional layer 53 may be disposed on the display panel 50, and the protective member 70 may be disposed under or below the display panel 50. In an embodiment, the input-sensing layer 400 may be further disposed on the display panel 50, wherein the input-sensing layer 400 receives a touch signal from a user. In an embodiment, the optical functional layer 53 may be disposed on the input-sensing layer 400. Hereinafter, for convenience of description, the case where both the optical functional layer 53 and the input-sensing layer 400 are disposed on the encapsulation member 300 of the display panel 50 is described in detail.

The optical functional layer 53 may include an anti-reflection layer. The anti-reflection layer may reduce reflectivity of light (external light) incident through the display apparatus 1 from the outside.

In an embodiment, the anti-reflection layer may include a polarizing film. The polarizing film may include a linear polarizing plate and a phase-retarding film such as a λ/4 (quarter-wave) plate. The phase-retarding film may be disposed on a touchscreen layer, and the linear polarizing plate may be disposed on the phase-retarding film.

In an embodiment, the anti-reflection layer may include a filter layer including a black matrix and color filters. The color filters may be arranged by taking into account colors of light emitted respectively from sub-pixels of the display apparatus 1. As an example, the filter layer may include a red, blue, or green color filter.

In an embodiment, the anti-reflection layer may include a destructive interference structure. The destructive interference structure may include a first reflection layer and a second reflection layer respectively disposed on different layers. First-reflected light and second-reflected light respectively reflected by the first reflection layer and the second reflection layer may destructively interfere and thus the reflectivity of external light may be reduced. Hereinafter, for convenience of description, the case where the optical functional layer 53 may include a polarizing film is described in detail.

Although not shown in the drawing, an adhesive member may be disposed between the optical functional layer 53 and the input-sensing layer 400. The adhesive member may attach the optical functional layer 53 to the display panel 50. The adhesive member may be a pressure sensitive adhesive (PSA) or a transparent adhesive member such as an optically clear adhesive (OCA) film. In an embodiment, the optical functional layer 53 may be directly disposed on the input-sensing layer 400 or the display panel 50 without a separate adhesive member.

The protective member 70 may be disposed under or below the display panel 50. The protective member 70 may sit on the lower surface of the main housing 11. The first adhesive member 80 may be disposed on the lower surface of the main housing 11 to fix the protective member 70 to the main housing 11.

The protective member 70 may absorb impacts applied from the outside. The protective member 70 may include layers. As an example, the protective member 70 may include a first layer 71, a second layer 72, and a third layer 73 that may be sequentially stacked. The first layer 71 may have an embossed shape. As an example, the first layer 71 may include protuberances. Each protuberance may protrude toward the display panel 50. The upper surface of the first layer 71 may have an uneven shape. The first layer 71 may have adhesive force. Through this, the first layer 71 may be attached to the rear surface of the substrate 100 of the display panel 50 described below. The first layer 71 may absorb impacts applied from the outside through the embossed shape. The second layer 72 may be disposed on one surface (or a surface) of the first layer 71. The second layer 72 may include a porous material. Through this, the second layer 72 may not only absorb impacts applied from the outside but also discharge heat occurring from the display panel 50 to the outside. The third layer 73 may include metal and be disposed on one side (or a side) of the second layer 72. As an example, the third layer 73 may include aluminum. The third layer 73 may have a plate shape and be disposed to cover the rear surface of the second layer 72 entirely.

The protective member 70 may include an opening into which the display controllers 40 and 41 are inserted. The opening may have a groove shape. As an example, the opening may include a first opening 73-1 and a second opening 72-1, wherein the first opening 73-1 completely passes through the third layer 73, and the second opening 72-1 is disposed to correspond to the first opening 73-1 and formed in a groove shape in the second layer 72. At least a portion of the second layer 72 may remain inside the opening. The thickness of a portion of the protective member 70 into which the display controllers 40 and 41 are inserted may be different from the thickness of another portion of the protective member 70. As an example, the thickness of the portion of the protective member 70 on which the display controllers 40 and 41 sit may be less than the thickness of another portion of the protective member 70. By way of example, the thickness of a first portion of the second layer 72 on which the display controllers 40 and 41 sit may be less than the thickness of the second portion, not the first portion of the second layer 72. Through this, because at least a portion of the display controllers 40 and 41 is inserted into the protective member 70, an interval between the rear surface of the display controllers 40 and 41 and the lower surface of the main housing 11 is sufficiently secured in a portion where the display controllers 40 and 41 are disposed. Accordingly, impacts applied to the display panel 50 depending on the transformation of the main housing 11 may be reduced.

At least a portion of the display controllers 40 and 41 may be inserted into the protective member 70. The display controllers 40 and 41 may include a display circuit board 40 and a display component 41. The display controllers 40 and 41 may control the display panel 50 according to a signal input from the outside. The display circuit board 40 may be fixed to the protective member 70 through the second adhesive member 90. As an example, the second adhesive member 90 may be disposed between the display circuit board 40 and the second layer 72 to fix one surface of the display circuit board 40 to the lower surface of the second opening 72-1 of the second layer 72.

The display circuit board 40 may be connected to the display panel 50 through the connection member 30. The connection member 30 may include a flexible printed circuit board. The connection member 30 is connected to the display panel 50 and the display circuit board 40 and may bend to dispose the display controllers 40 and 41 on the rear surface of the protective member 70.

The display component 41 may include a semiconductor chip generating control signals in case that controlling the display panel 50, and a connector connected to a cable and the like within the spirit and the scope of the disclosure.

The inner housing 60-1 may be disposed between the housing 10 and the lateral surface of the display panel 50. The inner housing 60-1 may include an opening area and expose at least one of the display components 41 to the outside through the opening area. The opening area may provide a path for connecting the display controllers 40 and 41 and the main circuit board to each other. The inner housing 60-1 may include a metal material. The inner housing 60-1 may electrically connect the display circuit board 40 and the third layer 73 to each other by being in contact with the display circuit board 40 and the third layer 73. Through this, the inner housing 60-1 may reduce the display circuit board 40 from being influenced by external noise. The inner housing 60-1 may protect the display circuit board 40 from impacts by shielding most of the display circuit board 40.

Although not shown in the drawing, the display controllers 40 and 41 may be connected to the main circuit board. The main circuit board may be connected to the display controllers 40 and 41 using a flexible printed circuit board and/or a cable and the like within the spirit and the scope of the disclosure.

The main circuit board may include a main processor (not shown), a camera apparatus (not shown), a main connector (not shown), and components (not shown). The main processor may include an integrated circuit. The camera apparatus may be disposed on both the front surface and the rear surface of the main circuit board, and each of the main processor and the main connector may be disposed on one of the front surface and the rear surface of the main circuit board.

The main processor may be configured to control all functions of the display apparatus 1. As an example, the main processor may output digital video data to the display controllers 40 and 41 to allow the display panel 50 to display images. The main processor may receive sensed data from a touch sensor driver (not shown). The main processor may determine whether a user directly touches a touchscreen according to sensed data, and execute an operation corresponding to a user's direct touch or proximity touch. As an example, the main processor may analyze sensed data and calculate a user's touch coordinates, and execute an application indicated by an icon the user touches, or perform an operation. The main processor may be an application processor including an integrated circuit, a central processing unit, or a system chip.

The camera apparatus processes image frames such as still images or moving images obtained by an image sensor in a camera mode, and may output the image frames to the main processor. The camera apparatus may include at least one of a camera sensor (for example, a charge-coupled device (CCD), a complementary metal oxide semiconductor (CMOS), and the like), a photo sensor (or an image sensor), and a laser sensor. The camera apparatus may be connected to an image sensor among components overlapping a component area and may process images input to the image sensor.

A cable that passes through a cable hole of a bracket may be connected to the main connector, and accordingly, the main circuit board may be electrically connected to the display controller.

In addition to the main processor, the camera apparatus, and the main connector, the main circuit board may further include at least one of wireless communication parts, at least one of input units, at least one of sensor parts, at least one of output units, at least one of interface parts, a memory, and a power supply part.

The wireless communication part may include at least one of a broadcasting receiving module, a mobile communication module, a wireless Internet module, a short distance communication module, and a location information module.

The broadcasting receiving module may be configured to receive broadcasting signals and/or broadcasting-related information from an external broadcasting management server through a broadcasting channel. The broadcasting channel may include satellite channels, and/or groundwave channels.

The mobile communication module may be configured to transmit/receive radio signals to/from at least one of a base station, an external terminal, and a server on a mobile communication network established according to technology standards for mobile communication or communication schemes (for example, Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), and the like). Wireless signals may include voice call signals, image communication call signals, or various types of data corresponding to text/multimedia message transmission/reception.

The wireless Internet module may denote a module for wireless Internet access. The wireless Internet module may be configured to transmit/receive radio signals on a communication network according to wireless Internet technologies. Examples of wireless Internet technologies include wireless local area network (WLAN), wireless-fidelity (Wi-Fi), Wi-Fi Direct, and digital living network alliance (DLNA).

The short distance communication module is for short range communication, and may support short distance communication by using at least one of Bluetooth™, Radio Frequency Identification (RFID), Infrared Data Association; IrDA (IrDA), Ultra Wideband (UWB), ZigBee, Near Field Communication (NFC), Wi-Fi, Wi-Fi Direct, and Wireless Universal Serial Bus (Wireless USB) technologies. The short distance communication module may support wireless communication between the display apparatus 1 and a wireless communication system, between the display apparatus 1 and another electronic device, or between the display apparatus 1 and a network in which another electronic device (or an external server) is located, through a short distance wireless area network. The short distance wireless area network may be a wireless personal area network. The other electronic device may be a wearable device that may exchange data, or operate with the display apparatus 1.

The position information module is a module for obtaining the position (or the current position) of the display apparatus 1. Representative examples of the position information module include a Global Positioning System (GPS) module or a Wi-Fi module. As an example, in case that the GPS module is utilized, the display apparatus 1 may obtain the position of the display apparatus 1 by using signals sent by GPS satellites. The display apparatus 1 may obtain the position of the display apparatus 1 based on information of a wireless access point (AP) that transmits/receives radio signals to/from the Wi-Fi module by using the Wi-Fi module. The position information module is not limited to a module for directly calculating or obtaining the position of the display apparatus 1.

The input unit may include an image input unit such as the camera apparatus for inputting image signals, a sound input unit such as a microphone for inputting sound signals, and the input unit for receiving information from a user.

The camera apparatus processes image frames such as still images or moving images obtained by an image sensor in an image communication mode or a photographing mode. The processed image frames may be displayed on the display panel 50 or stored in the memory.

The microphone processes external sound signals as electrical voice data. The processed voice data may be variously utilized according to a function (or an application in execution) being performed in the display apparatus 1. Various noise cancelling algorithms may be implemented in the microphone, wherein the various noise cancelling algorithms cancel noises occurring during a process of receiving external sound signals.

The main processor may control an operation of the display apparatus 1 to correspond to information input through the input unit. The input unit may include a mechanical input means such as buttons, a dome switch, a jog wheel, a jog switch, and the like, or a touch input means located on the lower surface or the lateral surface of the display apparatus 1. The touch input means may include the touchscreen layer of the display panel 50.

The sensor part may include at least one sensor that senses at least one of information inside the display apparatus 1, peripheral environmental information surrounding the display apparatus 1, and user information, and generates sensing signals corresponding thereto. The main processor may control driving or an operation of the display apparatus 1 based on the sensing signals, or perform data processing, a function, or an operation related to an application installed in the display apparatus 1. The sensor part may include at least one of a proximity sensor, an illumination sensor, an acceleration sensor, a magnetic sensor, a G-sensor, a gyroscope sensor, a motion sensor, an RGB sensor, an infrared sensor, a finger scan sensor, an ultrasonic sensor, an optical sensor, a battery gauge, an environment sensor (for example, a barometer, a hygrometer, a thermometer, a radiation detection sensor, a heat detection sensor, a gas detection sensor, and the like), a chemical sensor (for example, an electronic nose, a healthcare sensor, a biometric sensor, and the like).

A proximity sensor denotes a sensor that detects whether there is an object approaching a preset detection surface or an object existing in the neighborhood by using electromagnetic force, an infrared ray, or the like without a mechanical contact. Examples of the proximity sensor include a transmissive photo-electric sensor, a direct reflective photo-electric sensor, a mirror reflective photo-electric sensor, a high-frequency oscillation type proximity sensor, a capacitance type proximity sensor, a magnetic proximity sensor, and an infrared proximity sensor. The proximity sensor may sense not only a proximity touch, but also a proximity touch pattern such as a proximity touch distance, a proximity touch direction, a proximity touch velocity, a proximity touch time, a proximity touch position, and a proximity touch movement state. The main processor may process data (or information) corresponding to a proximity touch operation and a proximity touch pattern sensed by the proximity sensor, and control the display panel 50 to display visual information corresponding to the processed data.

The ultrasonic sensor may recognize the position information of an object by using ultrasonic waves. The main processor may calculate the position of an object by using information sensed by an optical sensor and ultrasonic sensors. Because the velocity of light is different from the velocity of ultrasonic waves, the position of an object may be calculated by using a time during which light reaches a light sensor and a time during which ultrasonic waves reach the ultrasonic sensor.

The output unit is intended to generate an output related to vision, hearing, or tactile sensation, and may include at least one of the display panel 50, a sound output unit, a haptic module, and a light output unit.

The sound output unit may output sound data received by the wireless communication unit or stored in the memory in a call reception mode, a communication mode or recoding mode, a voice recognition mode, a broadcasting reception mode, and the like within the spirit and the scope of the disclosure. The sound output unit may output sound signals related to a function (for example, a call signal reception tone, a message reception tone, and the like) performed by the display apparatus 1. The sound output unit may include a receiver and a speaker. At least one of the receiver and the speaker may be a sound generator that is attached under or below the display panel 50 and vibrates the display panel 50 to output sounds. The sound generator may be a piezoelectric element or a piezoelectric actuator that contacts and expands according to electrical signals, or an exciter that generates magnetic force by using a voice coil to vibrate the display panel 50.

The haptic module generates various haptic effects that may be felt by a user. The haptic module may provide vibrations to a user as a haptic effect. The intensity, the pattern, and the like of vibrations generated by the haptic module may be controlled by a user's selection or setting of the main processor. As an example, the haptic module may synthesize different vibrations to output the same, or sequentially output the different vibrations. The haptic module may generate various tactile effects such as effects due to stimulus of the arrangement of pins that move perpendicular to the surface of a skin in contact, the blowing force or suction power of air through a nozzle or a suction port, sweep to the skin surface, an electrode contact, electrostatic force, etc. and effects due to reproduction of cool and warm feeling using elements that may absorb heat or generate heat, as well as vibrations. The haptic module may not only transfer a tactile effect through a direct contact but implement a tactile effect such that a user may feel the tactile effect through a muscle sense in fingers or arms.

The light output unit outputs signals for informing occurrence of an event by using light of a light source. Examples of an event generated in the display apparatus 1 may include message reception, call signal reception, a missed call, alarm, schedule notification, e-mail reception, information reception through an application, and the like within the spirit and the scope of the disclosure. Signals output by the light output unit are implemented in case that the display apparatus 1 emits light of a single color or colors to the front surface or the rear surface. The signal output may end in case that the display apparatus 1 detects that a user confirms an event.

The interface part serves as a path with various kinds of external apparatuses connected to the display apparatus 1. The interface part may include at least one of a wired/wireless headset port, an external charger port, a wired/wireless data port, a memory card part, a port for connecting an apparatus having an identification module, an audio input/output (I/O) port, a video I/O port, and an earphone port. In case that an external apparatus is connected to the interface part, the display apparatus 1 may perform an appropriate control related to the external apparatus connected.

The memory stores data that support various functions of the display apparatus 1. The memory may store application programs driven in the display apparatus 1, data for operations of the display apparatus 1, and commands. At least some of the application programs may be downloaded from an external server through wireless communication. The memory may store an application program for operations of the main processor, and temporarily store data input/output, for example, data such as a phone book, messages, still images, moving images, and the like within the spirit and the scope of the disclosure. The memory may be configured to store haptic data for vibration of various patterns provided to the haptic module, and sound data related to various sounds provided to the sound output unit. The memory may include at least one type of storing medium among a flash memory type, a hard disk type, a solid state disk (SSD) type, a silicon disk drive (SDD) type, a multimedia card micro type, a card type memory (for example, secure digital (SD) or extreme digital (XD) memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk.

The power supply part receives an external power and an internal power under control of the main processor, and may supply power to respective elements included in the display apparatus 1. The power supply part may include a battery. The power supply part may include a connection port. The connection port may be configured as an example of the interface part to which an external charger is electrically connected, wherein the external charger supplies power to charge the battery. By way of example, the power supply part may be configured to charge the battery wirelessly without using the connection port. The battery may receive power from an external wireless power transfer apparatus by using at least one of inductive coupling and magnetic resonance coupling, wherein the inductive coupling is based on magnetic induction, and the magnetic resonance coupling is based on electromagnetic resonance. The battery may be arranged in a third direction (a Z direction) not to overlap the main circuit board. The battery may overlap a battery hole of the bracket.

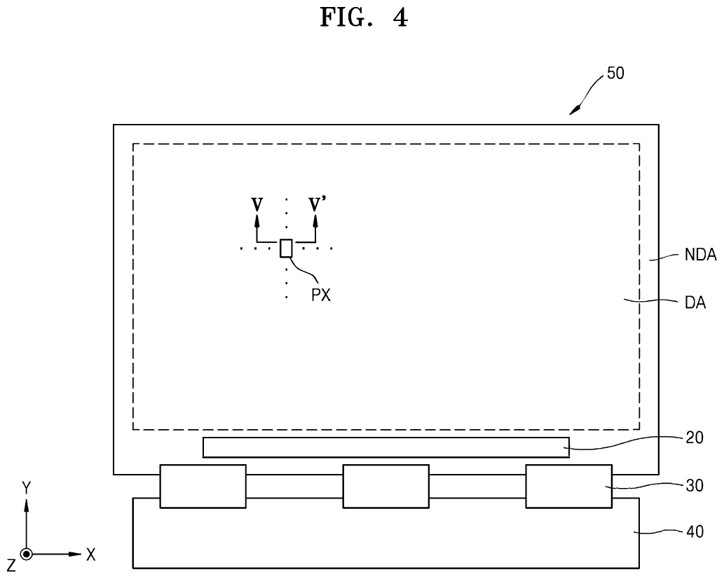

FIG. 4 is a schematic plan view of the display panel 50, the connection member 30, and the display controller shown in FIG. 2.

Referring to FIG. 4, the display panel 50 may include a display area DA in which images are displayed, and a peripheral area NDA arranged around the display area DA. The display panel DA may include a first surface including the display area DA, and a second surface different from the first surface. Sub-pixels PX each including a display element may be arranged in the display area DA. The sub-pixel PX may be provided in plurality, and the sub-pixels PX may be arranged to be apart from each other. Some of the sub-pixels PX, others of the sub-pixels PX, and still others of the sub-pixels PX may be configured to emit light of different colors. The display apparatus 1 may be configured to display images using light emitted from the sub-pixels PX arranged in the display area DA, and the peripheral area NDA may be a region in which the sub-pixels PX are not arranged.

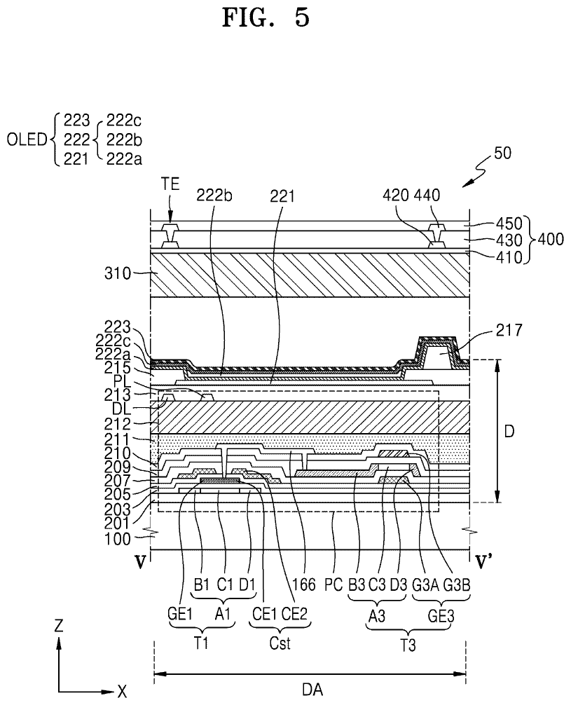

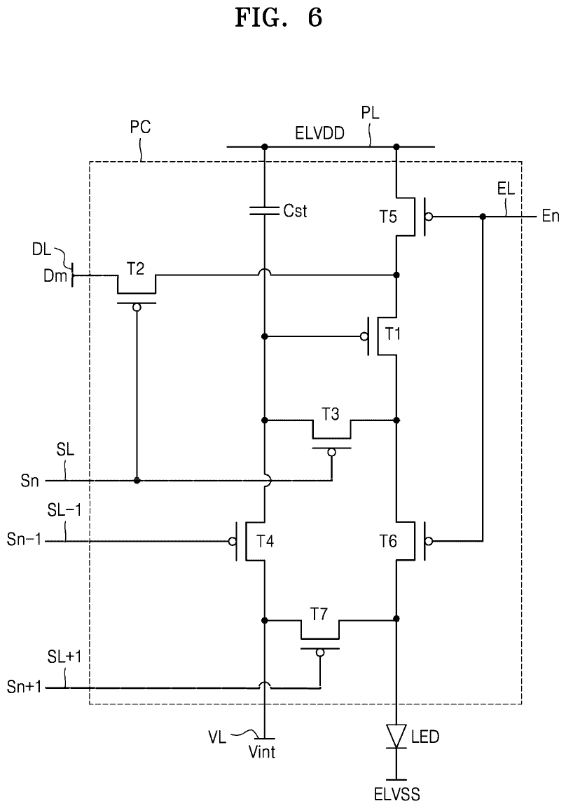

In the display panel 50, the sub-pixels PX arranged in the display area DA may be configured to emit red, green, and blue light by using light-emitting diodes arranged in relevant positions corresponding to respective sub-pixels PX. Transistors and signal lines, for example, data lines DL (see FIG. 5) and scan lines SL (see FIG. 6) may be arranged in the display area DA, wherein the transistors are electrically connected to the light-emitting diodes, and the signal lines are electrically connected to a storage capacitor. The data lines DL may extend in a Y direction in the display area DA, and the scan lines SL may extend in an X direction in the display area DA.

The peripheral area NDA may be outside of the display area DA and may surround the display area DA entirely.

Although not shown in the drawing, a scan driver may be arranged in the peripheral area NDA and electrically connected to scan lines. The scan driver generates scan signals, the generated scan signals may be transferred to a transistor electrically connected to a light-emitting diode through the scan line.

The scan drivers may be provided in pairs, and the pair of scan drivers may be arranged on both sides of the display area DA.

Although not shown in the drawing, a driving voltage supply line and a common voltage supply line are arranged in the peripheral area NDA. The driving voltage supply line may be arranged between one lateral side (or a lateral side) of the substrate 100 on which a pad part is arranged, and display area DA. The common voltage supply line may be arranged in the peripheral area NDA and may have a loop shape having one open side (or an open side) and extending along the display area DA. The common voltage supply line may extend along the other sides except for one lateral side of the substrate 100 on which a terminal part is disposed.

A display driver 20 may be arranged in the peripheral area NDA. The display driver 20 may be arranged between one lateral side of the substrate 100 on which the pad part is arranged, and display area DA. The display driver 20 may include a data driver. In the specification, the display driver 20 may represent a data driver. The display driver 20 may be electrically connected to a pad terminal disposed below the display driver 20. Data signals generated by the display driver 20, for example, the data driver, may be transferred to a signal line arranged in the display area DA, for example, the data line through a connection line arranged in the peripheral area NDA.

The display driver 20 may be directly disposed on the substrate 100 of the display panel 50. The display panel 50 and the display circuit board 40 may be connected to each other using the connection member 30 and the like within the spirit and the scope of the disclosure.

The pad part (not shown) may include terminals. The terminals may be connected to the connection member 30 and thus connected to the display circuit board 40. The display component 41 disposed on the display circuit board 40 may generate control signals for controlling a driver and the display driver 20, and the generated control signals may be transferred to the scan driver and the display driver 20 through the pad part. The display component 41 may respectively transfer a driving voltage and a common voltage to the driving voltage supply line and the common voltage supply line through the pad part.

FIG. 5 is a schematic cross-sectional view of a portion of the display panel 50, taken along line V-V′ of FIG. 4.

Referring to FIG. 5, the display panel 50 may include the substrate 100, the display layer D, a sealing member (not shown), the encapsulation substrate 310, and the input-sensing layer 400.

The display layer D may include a sub-pixel circuit PC and a light-emitting diode arranged in the display area DA of the display panel 50. The light-emitting diode may include an organic light-emitting diode OLED. Referring to FIG. 5, the display layer D may include layers from a buffer layer 201 to a spacer 217 on the substrate 100.

The substrate 100 may include glass or polymer resin. In an embodiment, the substrate 100 may have a stack structure in which a base layer including a polymer resin and a barrier layer including an inorganic insulating material such as silicon oxide or silicon nitride may be alternately stacked. In the case where the substrate 100 may include the stack structure of the base layer of the polymer resin and the barrier layer of the inorganic insulating material as described above, because the flexibility of the display apparatus 1 improves as described above with reference to FIG. 1, the foldable display apparatus 1 may be provided.

The polymer resin may include polyethersulfone, polyarylate, polyetherimide, polyethylene naphthalate, polyethylene terephthalate, polyphenylene sulfide, polyimide, polycarbonate, cellulose tri acetate, cellulose acetate propionate, or the like within the spirit and the scope of the disclosure.

The sub-pixel circuit PC may be formed on the substrate 100, and the light-emitting diode, for example, the organic light-emitting diode OLED may be formed on the sub-pixel circuit PC.

The buffer layer 201 may be formed on the substrate 100 before the sub-pixel circuit PC is formed to prevent impurities from penetrating to the sub-pixel circuit PC. The buffer layer 201 may include an inorganic insulating material such as silicon nitride, silicon oxynitride, and silicon oxide, and include a single-layered structure or a multi-layered structure including the above inorganic insulating materials.

As described with reference to FIG. 6, the sub-pixel circuit PC may include transistors and a storage capacitor. With regard to this, FIG. 5 shows a first thin-film transistor T1, a third thin-film transistor T3, and a storage capacitor Cst.

The first thin-film transistor T1 may include a semiconductor layer (referred to as a first semiconductor layer A1) on the buffer layer 201, and a gate electrode (referred to as a first gate electrode GE1) overlapping a channel region C1 of the first semiconductor layer A1. The first semiconductor layer A1 may include a silicon-based semiconductor material, for example, polycrystalline silicon. The first semiconductor layer A1 may include the channel region C1, a first region B1, and a second region D1 respectively disposed on two opposite sides of the channel region C1. The first region B1 and the second region D1 are regions including impurities of higher concentration than that of the channel region C1. One of the first region B1 and the second region D1 may correspond to a source region, and the other may correspond to a drain region.

A first gate insulating layer 203 may be disposed between the first semiconductor layer A1 and the first gate electrode GE1. The first gate insulating layer 203 may include an inorganic insulating material such as silicon nitride, silicon oxynitride, and silicon oxide, and include a single-layered structure or a multi-layered structure including the above inorganic insulating materials.

The first gate electrode GE1 may include a conductive material including molybdenum (Mo), aluminum (A1), copper (Cu), and titanium (Ti) and have a single-layered structure or a multi-layered structure including the above materials.

The storage capacitor Cst may include a lower electrode CE1 and an upper electrode CE2 overlapping each other. In an embodiment, the lower electrode CE1 of the storage capacitor Cst may include the first gate electrode GE1. In other words, the first gate electrode GE1 may include the lower electrode CE1 of the storage capacitor Cst. As an example, the first gate electrode GE1 and the lower electrode CE1 of the storage capacitor Cst may be integral.

A first interlayer insulating layer 205 may be disposed between the lower electrode CE1 and the upper electrode CE2 of the storage capacitor Cst. The first interlayer insulating layer 205 may include an inorganic insulating material such as silicon nitride, silicon oxynitride, and silicon oxide, and include a single-layered structure or a multi-layered structure including the above inorganic insulating materials.

The upper electrode CE2 of the storage capacitor Cst may include a conductive material of a low-resistance material such as molybdenum (Mo), aluminum (A1), copper (Cu) and/or titanium (Ti), and have a single-layered structure or a multi-layered structure including the above materials.

A second interlayer insulating layer 207 may be disposed on the storage capacitor Cst. The second interlayer insulating layer 207 may include an inorganic insulating material such as silicon nitride, silicon oxynitride, and silicon oxide, and include a single-layered structure or a multi-layered structure including the above inorganic insulating materials.

A semiconductor layer (referred to as a third semiconductor layer A3) of the third thin-film transistor T3 may be disposed on the second interlayer insulating layer 207. The third semiconductor layer A3 may include an oxide-based semiconductor material. As an example, the third semiconductor layer A3 may include Zn-oxide-based material, for example, include Zn-oxide, In—Zn oxide, and Ga—In—Zn oxide. In an embodiment, the third semiconductor layer A3 may include In—Ga—Zn—O (IGZO), In—Sn—Zn—O (ITZO), or In—Ga—Sn—Zn—O (IGTZO) semiconductor containing metal such as indium (In), gallium (Ga), and stannum (Sn) in ZnO.

The third semiconductor layer A3 may include a channel region C3, a first region B3, and a second region D3 respectively disposed on two opposite sides of the channel region C3. One of the first region B3 and the second region D3 may correspond to a source region, and the other may correspond to a drain region.

The third thin-film transistor T3 may include a gate electrode (referred to as a third gate electrode GE3, hereinafter) overlapping the channel region C3 of the third semiconductor layer A3. The third gate electrode GE3 may have a double gate structure including a lower gate electrode G3A and an upper gate electrode G3B, wherein the lower gate electrode G3A is below the third semiconductor layer A3, and the upper gate electrode G3B is over the channel region C3.

The lower gate electrode G3A may be on the same layer (for example, the first interlayer insulating layer 205) as the upper electrode CE2 of the storage capacitor Cst. The lower gate electrode G3A and the upper electrode CE2 of the storage capacitor Cst may include a same material.

The upper gate electrode G3B may be disposed over the third semiconductor layer A3 with a second gate insulating layer 209 therebetween. The second gate insulating layer 209 may include an inorganic insulating material such as silicon nitride, silicon oxynitride, and silicon oxide, and include a single-layered structure or a multi-layered structure including the above inorganic insulating materials.

A third interlayer insulating layer 210 may be disposed on the upper gate electrode G3B. The third interlayer insulating layer 210 may include an inorganic insulating material such as silicon oxynitride, and have a single layer or a multi-layer including the inorganic insulating materials.

Although FIG. 5 shows the first thin-film transistor T1 and the third thin-film transistor T3 among the thin-film transistors, and the first semiconductor layer A1 and the third semiconductor layer A3 are disposed on different layers as described below with reference to FIG. 6, the disclosure is not limited thereto.

The second, fifth, sixth, and seventh thin-film transistors T2, T5, T6, and T7 described below with reference to FIG. 6 may have the same structure as the first thin-film transistor T1 described with reference to FIG. 5. As an example, the second, fifth, sixth, and seventh thin-film transistors T2, T5, T6, and T7 may include a semiconductor layer disposed on the same layer as the first semiconductor layer A1 of the first thin-film transistor T1, and a gate electrode disposed on the same layer as the first gate electrode GE1 of the first thin-film transistor T1. The semiconductor layers of the second, fifth, sixth, and seventh thin-film transistors T2, T5, T6, and T7 may be integrally connected to the first semiconductor layer A1.

The fourth thin-film transistor T4 (see FIG. 6) described below with reference to FIG. 6 may have the same structure as that of the third thin-film transistor T3 described with reference to FIG. 5. As an example, the fourth thin-film transistor T4 may include a semiconductor layer disposed on the same layer as the third semiconductor layer A3 of the third thin-film transistor T3, and a gate electrode formed on the same layer as the third gate electrode GE3 of the third thin-film transistor T3. A semiconductor layer of the fourth thin-film transistor T4 may be integrally connected to the third semiconductor layer A3 of the third thin-film transistor T3.

The first thin-film transistor T1 may be electrically connected to the third thin-film transistor T3 through a node connection line 166. The node connection line 166 may be disposed on the third interlayer insulating layer 210. One side of the node connection line 166 may be connected to the first gate electrode GE1 of the first thin-film transistor T1, and the other side of the node connection line 166 may be connected to the third semiconductor layer A3 of the third thin-film transistor T3.

The node connection line 166 may include aluminum (A1), copper (Cu), and/or titanium (Ti), and include a single layer or a multi-layer including the above materials. As an example, the node connection line 166 may have a three-layered structure of titanium layer/aluminum layer/titanium layer.

A first organic insulating layer 211 may be disposed on the node connection line 166. The first organic insulating layer 211 may include an organic insulating material. The organic insulating material may include acryl, benzocyclobutene (BCB), polyimide, or hexamethyldisiloxane (HMDSO).

A second organic insulating layer 212 may be disposed on the first organic insulating layer 211. The second organic insulating layer 212 may include a material identical or similar to that of the first organic insulating layer 211. The second organic insulating layer 212 may be integral with the first organic insulating layer 211, or formed separately from the first organic insulating layer 211 and stacked on the first organic insulating layer 211.

The data line DL and the driving voltage line PL may be disposed on the first organic insulating layer 211 or the second organic insulating layer 212, and may be covered by the second organic insulating layer 212 or a third organic insulating layer 213. Hereinafter, for convenience of description, the case where the data line DL and the driving voltage line PL are disposed on the second organic insulating layer 212 and covered by the third organic insulating layer 213 is described in detail.

The data line DL and the driving voltage line PL may include aluminum (A1), copper (Cu), and/or titanium (Ti), and include a single layer or a multi-layer including the above materials. As an example, the data line DL and the driving voltage line PL may each have a three-layered structure of titanium layer/aluminum layer/titanium layer.

The third organic insulating layer 213 may include acryl, BCB, polyimide, and/or HMDSO. Although it is shown in FIG. 5 that the data line DL and the driving voltage line PL are disposed on the second organic insulating layer 212, the disclosure is not limited thereto. In an embodiment, one of the data line DL and the driving voltage line PL may be disposed on the same layer (for example, the third interlayer insulating layer 210) as the node connection line 166.

The light-emitting diode, for example, the organic light-emitting diode OLED may be disposed on the third organic insulating layer 213.

A first electrode 221 of the organic light-emitting diode OLED may include a reflective layer including silver (Ag), magnesium (Mg), aluminum (A1), platinum (Pt), palladium (Pd), gold (Au), nickel (Ni), neodymium (Nd), iridium (Ir), chrome (Cr), or a compound thereof. In an embodiment, the first electrode 221 may further include a conductive oxide material layer on and/or under or below the reflective layer. The conductive oxide material layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the first electrode 221 may have a three-layered structure of ITO layer/Ag layer/ITO layer.

A bank layer 215 may be disposed on the first electrode 221. The bank layer 215 may include an opening that overlaps the first electrode 221 and cover the edges of the first electrode 221. The bank layer 215 may include an organic insulating material such as polyimide.

An intermediate layer 222 may include an emission layer 222b. The intermediate layer 222 may include a first functional layer 222a and/or a second functional layer 222c, wherein the first functional layer 222a is under or below the emission layer 222b, and the second functional layer 222c is on the emission layer 222b. The emission layer 222b may include a polymer organic material or a low-molecular weight organic material configured to emit light having a preset color. The second functional layer 222c may include an electron transport layer (ETL) and/or an electron injection layer (EIL). The first functional layer 222a and the second functional layer 222c may each include an organic material.

A second electrode 223 may include a conductive material having a low work function. As an example, the second electrode 223 may include a (semi) transparent layer including silver (Ag), magnesium (Mg), aluminum (A1), platinum (Pt), palladium (Pd), gold (Au), nickel (Ni), neodymium (Nd), iridium (Ir), chrome (Cr), or an alloy thereof. By way of example, the second electrode 223 may further include a layer on the (semi) transparent layer, the layer including ITO, IZO, ZnO, or In₂O₃.

The emission layer 222b may be formed in the display area DA to overlap the first electrode 221 through the opening of the bank layer 215. In contrast, the first functional layer 222a, the second functional layer 222c, and the second electrode 223 may cover the display area DA entirely.

The spacer 217 may be formed on the bank layer 215. The spacer 217 may be formed together with the bank layer 215 during the same process as a process of forming the bank layer 215, or formed separately during a separate process. In an embodiment, the spacer 217 may include an organic insulating material such as polyimide. By way of example, the bank layer 215 may include an organic insulating material including a light-blocking dye, and the spacer 217 may include an organic insulating material such as polyimide.

The organic light-emitting diode OLED may be covered by an encapsulation member (not shown). The encapsulation member may include a sealing member (not shown) and the encapsulation substrate 310. The sealing member may be formed in a form of resin, and disposed and cured on the substrate 100 to couple or connect the substrate 100 and the encapsulation substrate 310 to each other. Because the encapsulation substrate 310 is identical or similar to the substrate 100, detailed description thereof may be omitted.

The input-sensing layer 400 may be disposed on the encapsulation substrate 310. The input-sensing layer 400 may include touch electrodes TE and at least one touch insulating layer arranged in the display area DA. With regard to this, it is shown in FIG. 5 that the input-sensing layer 400 may include a first touch insulating layer 410, a first conductive line 420, a second touch insulating layer 430, a second conductive line 440, and a third touch insulating layer 450, wherein the first touch insulating layer 410 is on the encapsulation substrate 310, the first conductive line 420 is on the first touch insulating layer 410, the second touch insulating layer 430 is on the first conductive line 420, the second conductive line 440 is on the second touch insulating layer 430, and the third touch insulating layer 450 is on the second conductive line 440.

The first touch insulating layer 410, the second touch insulating layer 430, and the third touch insulating layer 450 may each include an inorganic insulating material and/or an organic insulating material. In an embodiment, the first touch insulating layer 410 and the second touch insulating layer 430 may each include an inorganic insulating material such as silicon oxide, silicon nitride, and/or silicon oxynitride, and the third touch insulating layer 450 may include an organic insulating material. At least one of the first touch insulating layer 410, the second touch insulating layer 430, and the third touch insulating layer 450 may extend from the display area DA to the peripheral area NDA.

The touch electrode TE of the input-sensing layer 400 may have a structure in which the first conductive line 420 is connected to the second conductive line 440. By way of example, the touch electrode TE may include one of the first conductive line 420 and the second conductive line 440. The second touch insulating layer 430 may be omitted.

Each of the first conductive line 420 and the second conductive line 440 may include aluminum (A1), copper (Cu), and/or titanium (Ti), and include a single layer or a multi-layer including the above materials. As an example, each of the first conductive line 420 and the second conductive line 440 may have a triple-layered structure of titanium layer/aluminum layer/titanium layer.

FIG. 6 is a schematic diagram of an equivalent circuit of a sub-pixel circuit PC shown in FIG. 5.

Referring to FIG. 6, as described above with reference to FIG. 4, each sub-pixel PX (see FIG. 4) may be configured to emit light using a light-emitting diode. A light-emitting diode may be electrically connected to a sub-pixel circuit PC.

The sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

The second thin-film transistor T2 is a switching thin-film transistor, may be connected to a scan line SL and a data line DL, and configured to transfer a data voltage (or a data signal Dm) to the first thin-film transistor T1 based on a switching voltage (or a switching signal Sn), the data voltage being input from the data line DL, and the switching voltage being input from the scan line SL. The storage capacitor Cst may be connected to the first thin-film transistor T1 and a driving voltage line PL and configured to store a voltage corresponding to a difference between a voltage transferred from the second thin-film transistor T2 and a driving voltage ELVDD supplied to the driving voltage line PL.

The first thin-film transistor T1 is a driving thin-film transistor, may be connected to the driving voltage line PL and the storage capacitor Cst, and configured to control a driving current according to the voltage stored in the storage capacitor Cst, the driving current flowing from the driving voltage line PL to a light-emitting diode LED. The light-emitting diode LED may emit light having a preset brightness corresponding to the driving current. A second electrode (for example, a cathode) of the light-emitting diode LED may be configured to receive a common power voltage ELVSS.

The third thin-film transistor T3 is a compensation thin-film transistor, and a gate electrode of the third thin-film transistor T3 may be connected to the scan line SL. A source electrode (or a drain electrode) of the third thin-film transistor T3 may be connected to a first electrode of the light-emitting diode LED through the sixth thin-film transistor T6 while being connected to a drain electrode (or a source electrode) of the first thin-film transistor T1. A drain electrode (or a source electrode) of the third thin-film transistor T3 may be connected to one of electrodes of the storage capacitor Cst, a source electrode (or a drain electrode) of the fourth thin-film transistor T4, and the gate electrode of the first thin-film transistor T1. The third thin-film transistor T3 is turned on according to a scan signal Sn received through the scan line SL and diode-connects the first thin-film transistor T1 by connecting the gate electrode and the drain electrode of the first thin-film transistor T1 to each other.

The fourth thin-film transistor T4 is an initialization thin-film transistor and a gate electrode thereof may be connected to a previous scan line SL-1. A drain electrode (or a source electrode) of the fourth thin-film transistor T4 may be connected to an initialization voltage line VL. A source electrode (or a drain electrode) of the fourth thin-film transistor T4 may be connected to one of the electrodes of the storage capacitor Cst, a drain electrode (or a source electrode) of the third thin-film transistor T3, and the gate electrode of the first thin-film transistor T1. The fourth thin-film transistor T4 may be turned on according to a previous scan signal Sn−1 received through the previous scan line SL−1 and may perform an initialization operation of initializing the voltage of the gate electrode of the first thin-film transistor T1 by transferring an initialization voltage Vint to the gate electrode of the first thin-film transistor T1.

The fifth thin-film transistor T5 is an operation control thin-film transistor, and a gate electrode thereof may be connected to an emission control line EL. A source electrode (or a drain electrode) of the fifth thin-film transistor T5 may be connected to the driving voltage line PL. The drain electrode (or the source electrode) of the fifth thin-film transistor T5 may be connected to the source electrode (or the drain electrode) of the first thin-film transistor T1, and the drain electrode (or the source electrode) of the second thin-film transistor T2.

The sixth thin-film transistor T6 is an emission control thin-film transistor, and a gate electrode thereof may be connected to the emission control line EL. A source electrode (or a drain electrode) of the sixth thin-film transistor T6 may be connected to the drain electrode (or the source electrode) of the first thin-film transistor T1, and the source electrode (or the drain electrode) of the third thin-film transistor T3. The drain electrode (or the source electrode) of the sixth thin-film transistor T6 may be electrically connected to the first electrode of the light-emitting diode LED. The fifth thin-film transistor T5 and the sixth thin-film transistor T6 may be simultaneously turned on according to an emission control signal En transferred through the emission control line EL, the driving voltage ELVDD is transferred to the light-emitting diode LED, and the driving current flows through the light-emitting diode LED.

The seventh thin-film transistor T7 may be an initialization thin-film transistor configured to initialize the first electrode of the light-emitting diode LED. A gate electrode of the seventh thin-film transistor T7 may be connected to a next scan line SL+1. The source electrode (or the drain electrode) of the seventh thin-film transistor T7 may be connected to the first electrode of the light-emitting diode LED. The drain electrode (or the source electrode) of the seventh thin-film transistor T7 may be connected to the initialization voltage line VL. The seventh thin-film transistor T7 may be turned on according to a next scan signal Sn+1 transferred through the next scan line SL+1 to initialize the first electrode of the light-emitting diode LED.

Although it is shown in FIG. 6 that the fourth thin-film transistor T4 and the seventh thin-film transistor T7 are respectively connected to the previous scan line SL−1 and the next scan line SL+1, both the fourth thin-film transistor T4 and the seventh thin-film transistor T7 may be connected to the previous scan line SL−1 and driven according to a previous scan signal Sn−1 in an embodiment.

Another electrode of the storage capacitor Cst may be connected to the driving voltage line PL. One of the electrodes of the storage capacitor Cst may be connected to the gate electrode of the first thin-film transistor T1, the drain electrode (or the source electrode) of the third thin-film transistor T3, and the source electrode (or the drain electrode) of the fourth thin-film transistor T4 together.

The second electrode (for example, a cathode) of the light-emitting diode LED is configured to receive the common power voltage ELVSS. The light-emitting diode LED is configured to emit light by receiving the driving current from the first thin-film transistor T1.

The light-emitting diode LED may be an organic light-emitting diode including an organic material as an emission material. In an embodiment, the light-emitting diode LED may be an inorganic light-emitting diode including an inorganic material. The inorganic light-emitting diode may include a PN-junction diode including inorganic material semiconductor-based materials. In case that a forward voltage is applied to a PN-junction diode, holes and electrons are injected and energy created by recombination of the holes and the electrons is converted to light energy, and thus, light of a preset color may be emitted. The inorganic light-emitting diode may have a width of several micrometers to hundreds of micrometers, or several nanometers to hundreds of nanometers. In an embodiment, the light-emitting diode LED may be a quantum-dot light-emitting diode. As described above, an emission layer of the light-emitting diode LED may include an organic material, an inorganic material, quantum dots, an organic material and quantum dots, or the inorganic material and quantum dots. Hereinafter, for convenience of description, the case where the light-emitting diode LED may include an organic light-emitting diode is described.

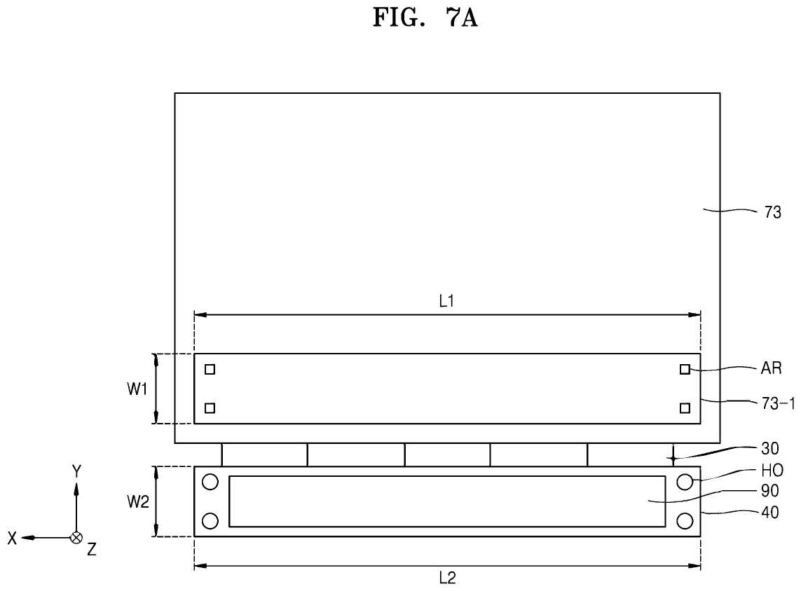

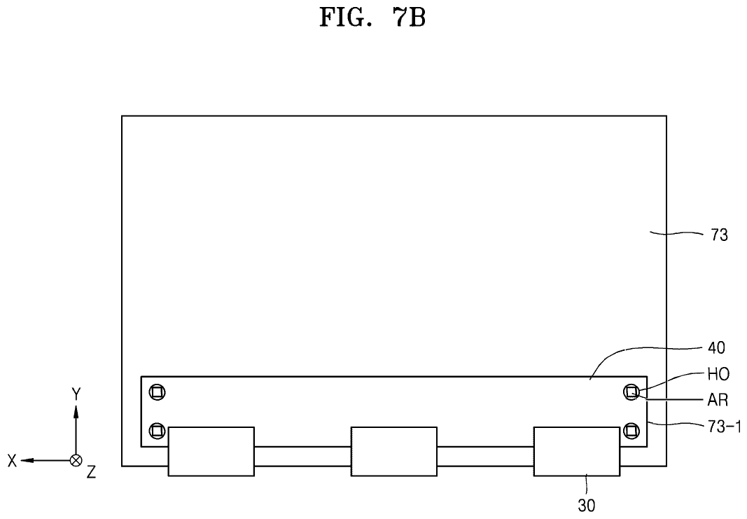

FIGS. 7A and 7B are schematic views showing an order of disposing a display controller of a display apparatus on the rear surface of the display panel 50 according to an embodiment.

Referring to FIG. 7A, the display circuit board 40 of the display controller may be connected to the display panel 50 through the connection member 30, and the display circuit board 40 may be disposed on the rear surface of the display panel 50 by bending the connection member 30. The second adhesive member 90 may be attached on one side of the display circuit board 40 or the lower surface of the opening of the protective member 70.

By way of example, the first opening 73-1 of the third layer 73 may be disposed on the protective member 70 disposed on the lower surface of the display panel 50. At least one first alignment mark AR may be disposed on the lower surface of the second opening (not shown) of the second layer (not shown). The first alignment mark AR may have various shapes. As an example, the first alignment mark AR may have an engraving or embossing shape disposed on the second layer 72. In an embodiment, the first alignment mark AR may be formed on the lower surface of the second opening of the second layer 72 through ink and the like within the spirit and the scope of the disclosure. The planar shape of the first alignment mark AR may be various. As an example, the planar shape of the first alignment mark AR may include at least one of a polygon, a circular shape, and an elliptical shape. In an embodiment, the planar shape of the first alignment mark AR may include an irregular shape such as a cross or a star. In an embodiment, the first alignment mark AR may be the second adhesive member 90. The second adhesive member 90 may be disposed on the lower surface of the opening. The second adhesive member 90 may have a shape identical or similar to that of the first alignment mark AR described above. However, for convenience of description, the case where the first alignment mark AR is marked on the lower surface using ink is described in detail.

A second alignment mark HO may be disposed on the display circuit board 40. The second alignment mark HO may have various shapes. As an example, the second alignment mark HO may include a transparent material. In an embodiment, the second alignment mark HO may have a form of a through hole passing through the display circuit board 40. The planar shape of the second alignment mark HO may be various. For example, in the case where the second alignment mark HO is disposed such that the center of the second alignment mark HO coincides with the center of the first alignment mark AR, the second alignment mark HO may include all shapes in which the first alignment mark AR is entirely shown.

A first width W1 of the opening may be equal to or greater than a second width W2 of the display circuit board 40. A first length L1 of the opening may be equal to or greater than a second length L2 of the display circuit board 40. Although it is shown that the planar shape of the opening and the planar shape of the display circuit board 40 are rectangular shapes, the disclosure is not limited thereto. For example, in an embodiment, the planar shape of the opening may correspond to the planar shape of the display circuit board 40. The planar shape of the opening may be greater than the planar shape of the display circuit board 40. In an embodiment, regardless of the planar shape of the display circuit board 40, in the case where the planar shape of the opening overlaps the planar shape of the display circuit board 40, the planar shape of the opening may include all shapes in which the planar shape of the display circuit board 40 is arranged inside the planar shape of the opening.

Referring to FIG. 7B, the connection member 30 is bent, and the positions of the first opening 73-1 and the display circuit board 40 may be aligned. In the aligning method, the display circuit board 40 is arranged to correspond to the first opening 73-1, the position of the display circuit board 40 is adjusted such that the first alignment mark AR and the second alignment mark HO overlap each other, relative positions of the first alignment mark AR and the second alignment mark HO, or the positions and the like of the center of the first alignment mark AR and the center of the second alignment mark HO are determined using a camera and the like, and accordingly, the position of the display circuit board 40 may be precisely adjusted such that the first alignment mark AR corresponds to the second alignment mark HO. Through this, in case that it is determined that the first alignment mark AR and the second alignment mark HO are aligned to each other, the display circuit board 40 may be attached to the protective member 70 by applying force to the display circuit board 40.

Although not shown in the drawing, the display apparatus may not have the first alignment mark AR and the second alignment mark HO. In the aligning method, in the case where there is a corner in the edges of the opening, the alignment may be performed by detecting the position of the corner to the position of a corner of the display circuit board 40. In an embodiment, the alignment may be performed by detecting the position of the second adhesive member 90 and the position of the display circuit board 40. The second adhesive member 90 may be disposed on the lower surface of the opening.

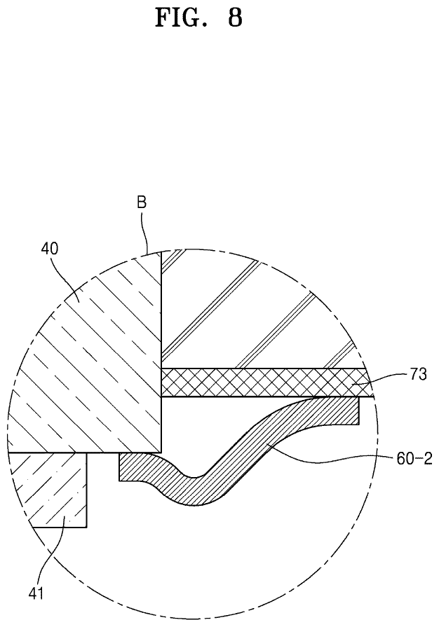

FIG. 8 is a schematic cross-sectional view of a portion of a display apparatus according to an embodiment. FIG. 8 is a schematic cross-sectional view of an enlarged view of a region B of FIG. 2

Referring to FIG. 8, the display apparatus (not shown) may include a housing (not shown), a display panel (not shown), an optical functional layer (not shown), a protective member (not shown), a connection member (not shown), the display controllers 40 and 41, and a wire portion 60-2. Because the housing, the display panel, the optical functional layer, the connection member, the protective member, and the display controllers 40 and 41 are identical or similar to those described with reference to FIGS. 1 to 3, detailed descriptions thereof may be omitted.

The display apparatus may include the wire portion 60-2 different from those shown in FIG. 2. The wire portion 60-2 may electrically connect the display circuit board 40 on which the display component 41 is disposed to the third layer 73. The wire portion 60-2 may be fixed to at least one of the display circuit board 40 and the third layer 73. The wire portion 60-2 may include a conductive material such as metal. Through this, the display controller 40 and 41 may be prevented from malfunctioning due to external noise.

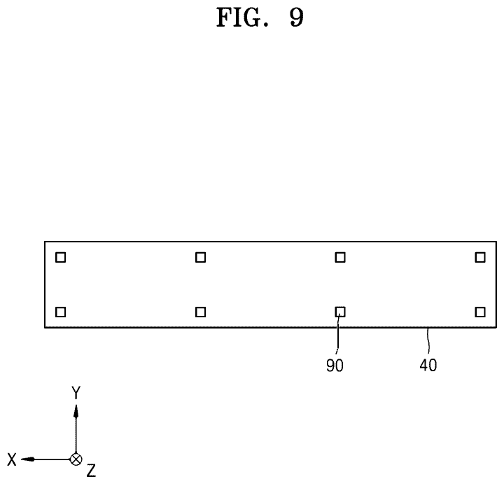

FIG. 9 is a schematic backside view of a portion of a display apparatus according to an embodiment.

Referring to FIG. 9, the display apparatus (not shown) may include a housing (not shown), a display panel (not shown), an optical functional layer (not shown), a connection member (not shown), a protective member (not shown), and a display controller (not shown). Because the housing, the display panel, the optical functional layer, the connection member, the protective member, and the display controller are identical or similar to those described with reference to FIGS. 1 to 3, detailed descriptions thereof may be omitted. For an electrical connection method between the display circuit board 40 and the third layer of the protective member, the method shown in FIG. 2 or FIG. 8 may be used.

The second adhesive member 90 disposed between the protective member and the display circuit board 40 may be provided in plurality. The second adhesive members 90 may be apart from each other.

Although not shown in the drawing, the second adhesive member 90 is not limited thereto and one second adhesive member 90 may be provided and the planar shape of the second adhesive member 90 may be a circular shape. In an embodiment, in the case where second adhesive members 90 are provided, the planar shape of one of the second adhesive members 90 may form a closed curve, and another of the second adhesive members 90 may be arranged inside or outside the closed curve.

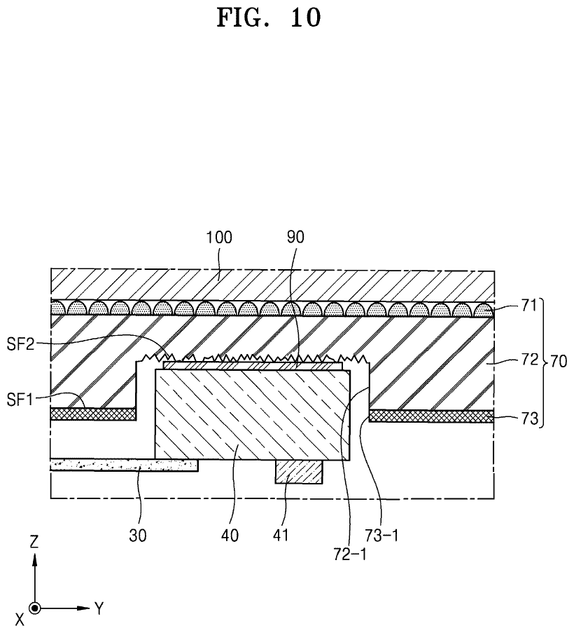

FIG. 10 is a schematic cross-sectional view of a portion of a display apparatus according to an embodiment.

Referring to FIG. 10, a display apparatus (not shown) may include a housing (not shown), a display panel (not shown), an optical functional layer (not shown), the connection member 30, the protective member 70, the display controllers 40 and 41, an inner housing (not shown), a first adhesive member (not shown), and the second adhesive member 90. Because the housing, the display panel, the optical functional layer, the connection member 30, the protective member 70, the display controllers 40 and 41, the inner housing, the first adhesive member, and the second adhesive member 90 are identical or similar to those described with reference to FIGS. 1 to 3, detailed descriptions thereof may be omitted.

The display circuit board 40 on which the display component 41 is disposed may be inserted inside the protective member 70 including the first layer 71, the second layer 72, and the third layer 73 that may be sequentially stacked from the rear surface of the substrate 100. The lateral surface of the first opening 73-1 and the lateral surface of the second opening 72-1 may be apart from the lateral surface of the display circuit board 40. For example, because the planar shape of the opening is formed larger than the planar shape of the display circuit board 40, the display circuit board 40 may be disposed inside the opening.

The roughness of the surfaces of the second layer 72 may be different from each other. As an example, the roughness of a second surface SF2 of the second layer 72 in contact with the second adhesive member 90 may be greater than the roughness of a first surface SF1 not in contact with the second adhesive member 90. For example, the second surface SF2 may include fine protuberances compared to the first surface SF1. Heat generated from the display controllers 40 and 41 may be effectively diffused to the second layer 72. The thickness of the protective member 70 corresponding to the first surface SF1 may be different from the thickness of the protective member 70 corresponding to the second surface SF2. For example, the thickness of the protective member 70 corresponding to the first surface SF1 may be greater than the thickness of the protective member 70 corresponding to the second surface SF2.

Although not shown in the drawing, the display apparatus may not have the inner housing and may have the wire portion as shown in FIG. 8.

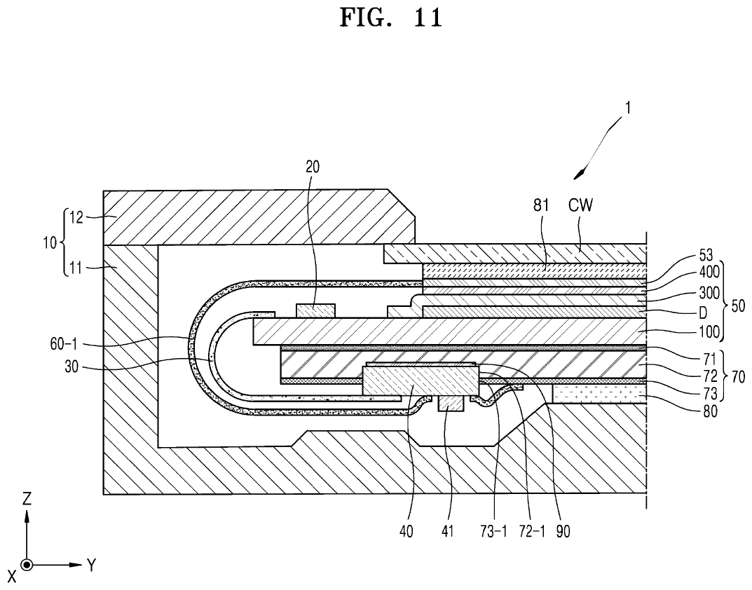

FIG. 11 is a schematic cross-sectional view of a portion of a display apparatus 1 according to an embodiment.

Referring to FIG. 11, the display apparatus 1 may include the housing 10, the display panel 50, the optical functional layer 53, the connection member 30, the protective member 70, the display controllers 40 and 41, the inner housing 60-1, the first adhesive member 80, the second adhesive member 90, a third adhesive member 81, and a cover member CW. The housing 10 may include the main housing 11 and the decorative housing 12. Because the housing 10 is identical or similar to that described with reference to FIGS. 1 to 3, detailed description thereof may be omitted. The display panel 50 may include the substrate 100, the display layer D, the encapsulation member 300, the input-sensing layer 400, and the display driver 20. Because the substrate 100, the display layer D, the input-sensing layer 400, and the display driver 20 are identical or similar to those described with reference to FIGS. 1 to 3, detailed descriptions thereof may be omitted. The protective member 70 may include the first layer 71, the second layer 72, and the third layer 73. The second layer 72 may include the second opening 72-1, and the third layer 73 may include the first opening 73-1. Because the protective member 70 is identical or similar to that described with reference to FIGS. 1 to 3, detailed description thereof may be omitted. Because the connection member 30, the display controllers 40 and 41, the inner housing 60-1, the first adhesive member 80, the second adhesive member 90, and the display driver 20 are identical or similar to those described with reference to FIGS. 1 to 3, detailed descriptions thereof may be omitted.

The cover member CW may be disposed on the optical functional layer 53. The cover member CW may include a transparent material. The cover member CW may include glass, synthetic resin of a transparent material, and the like within the spirit and the scope of the disclosure. The cover member CW may include at least one layer.

The cover member CW may be attached to the optical functional layer 53 by the third adhesive member 81. In an embodiment, the third adhesive member 81 may be a pressure sensitive adhesive (PSA) or a transparent adhesive member such as an optically clear adhesive (OCA).

Although not shown, in an embodiment, the cover member CW may include a transparent cover portion corresponding to the display panel 50, and a light-blocking cover portion corresponding to a region other than the display panel 50. The light-blocking cover portion may include an opaque material that blocks light. The light-blocking cover portion may include a pattern that may be viewed to a user while images are not displayed.

Although not shown in the drawing, a brush portion may be disposed between the decorative housing 12 and the cover member CW. The brush portion may block foreign material entering between the decorative housing 12 and the cover member CW. The brush portion may have fine fibers or protuberances and be in contact with the front surface of the cover member CW.

The display panel 50 may include the encapsulation member 300 which is an encapsulation member disposed on the display layer D. The display panel 50 may include at least one organic encapsulation layer and at least one inorganic encapsulation layer. In an embodiment, the encapsulation member 300 may include first and second inorganic encapsulation layers (not shown) and an organic encapsulation layer (not shown) therebetween. The first inorganic encapsulation layer may be disposed to shield the opposite electrode of FIG. 5, and the organic encapsulation layer and the second inorganic encapsulation layer may be sequentially stacked on the first inorganic encapsulation layer.

The first and second inorganic encapsulation layers may include at least one inorganic material among aluminum oxide, titanium oxide, tantalum oxide, hafnium oxide, zinc oxide, silicon oxide, silicon nitride, silicon oxynitride, and the like within the spirit and the scope of the disclosure. The first and second inorganic encapsulation layers may include a single layer or a multi-layer including the above materials. The organic encapsulation layer may include a polymer-based material. The polymer-based material may include an acryl-based resin, an epoxy-based resin, polyimide, and polyethylene. In an embodiment, the organic encapsulation layer may include acrylate.

The thickness of the first inorganic encapsulation layer may be different from that of the second inorganic encapsulation layer. The thickness of the first inorganic encapsulation layer may be greater than that of the second inorganic encapsulation layer. By way of example, the thickness of the second inorganic encapsulation layer may be greater than the thickness of the first inorganic encapsulation layer, or the thickness of the first inorganic encapsulation layer and the thickness of the second inorganic encapsulation layer may be identical to each other.

The input-sensing layer 400 may be disposed on the encapsulation member 300.

Impacts applied from outside the main housing 11 may be reduced from being transferred to the display panel 50 through the display circuit board 40.

Although not shown in the drawing, the display apparatus 1 may not have the inner housing 60-1 and may have the wire portion as shown in FIG. 8.

The display apparatus 1 may have the structure shown in FIG. 10.

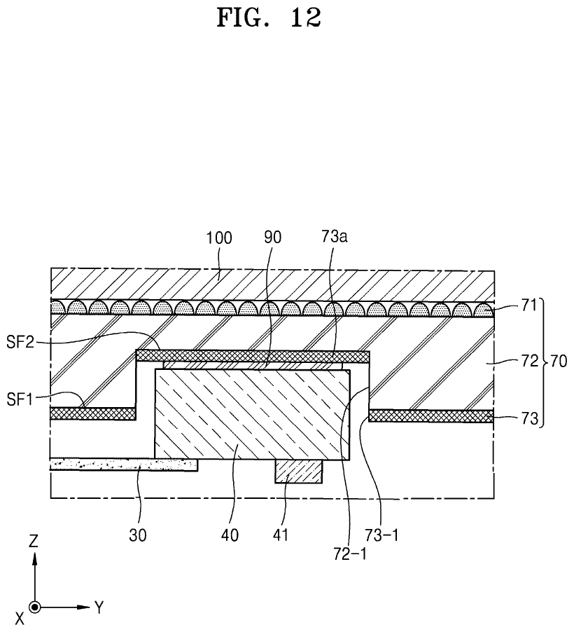

FIG. 12 is a schematic cross-sectional view of a portion of a display apparatus according to an embodiment.

Referring to FIG. 12, a display apparatus (not shown) may include a housing (not shown), a display panel (not shown), an optical functional layer (not shown), the connection member 30, the protective member 70, the display controllers 40 and 41, an inner housing (not shown), a first adhesive member (not shown), and the second adhesive member 90. Because the housing, the display panel, the optical functional layer, the connection member 30, the protective member 70, the display controllers 40 and 41, the inner housing, the first adhesive member, and the second adhesive member 90 are identical or similar to those described with reference to FIGS. 1 to 3, detailed descriptions thereof may be omitted.

The display circuit board 40 on which the display component 41 is disposed may be inserted inside the protective member 70 including the first layer 71, the second layer 72, and the third layer 73 that may be sequentially stacked from the rear surface of the substrate 100. The lateral surface of the first opening 73-1 and the lateral surface of the second opening 72-1 may be apart from the lateral surface of the display circuit board 40. For example, because the planar shape of the opening is formed larger than the planar shape of the display circuit board 40, the display circuit board 40 may be disposed inside the opening.

A fourth layer 73a similar to the third layer 73 may be disposed between the display circuit board 40 and the second layer 72. The fourth layer 73a may absorb heat emitted from at least one of the display circuit board 40 and the display panel 50.

Although not shown in the drawing, the display apparatus may not have the inner housing and may have the wire portion as shown in FIG. 8.

Similar to the display apparatus of FIG. 11, in the display apparatus, the display panel may have a structure including a encapsulation member and a cover member.

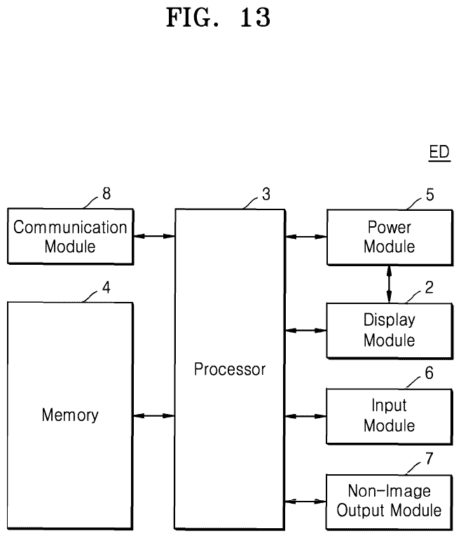

FIG. 13 is a block diagram of an electronic device ED according to an embodiment.

Referring to FIG. 13, the electronic device ED according to an embodiment may include a display module 2 including a display panel, a processor 3, a memory 4, and a power module 5.

The processor 3 may include at least one of a central processing unit (CPU), an application processor (AP), a graphics processing unit (GPU), a communication processor (CP), an image signal processor (ISP), and a controller. According to an embodiment, the processor 3 may be provided by being divided into two or more processors in a functional or structural perspective. For example, the processor 3 may include a main processor as a first driving chip including a CPU and an auxiliary processor as a second driving chip including a controller configured to receive an image signal from the main processor and process the image signal according to the interface specifications of the display module 2.

The memory 4 may include at least one of a non-volatile memory and a volatile memory. The memory 4 may store data information necessary for operations of the processor 3 or the display module 2. When the processor 3 executes an application stored in the memory 4e, an image data signal and/or an input control signal may be transmitted to the display module 2, and the display module 2 may be configured to process the received signal and output image information through a display screen.

The power module 5 may include a power supply module, such as a power adaptor or a battery device, and a power conversion module configured to convert a power supply from the power supply module and generate power necessary for operations of the electronic device ED. The power conversion by the power conversion module may include direct current (DC)-DC conversion, alternating current (AC)-DC conversion, and DC-AC conversion, but is not limited thereto.

The electronic device ED may further include an input module 6, a non-image output module 7, and/or a communication module 8.

The input module 6 may provide input information to the processor 3 and/or the display module 2. The input module 6 may include not only a physical button, a keyboard, and a microphone, but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors, such as a blood-pressure sensor, a blood-sugar sensor, an electrocardiogram sensor, a heart rate sensor, etc.

The non-image output module 7 may receive information except for an image from the processor 3 and provide the information to a user. Examples of the non-image output module 7 may include a sound module, a haptic module, a light-emission module, etc. and may also include other functionally intrinsic modules (for example, a cooling module of a refrigerator, etc.) of an electronic device ED.

The communication module 8 may be configured to perform transmission and reception of information between the electronic device ED and an external device and may include a receiver and a transmitter. The communication module 8 may include various wireless communication modules, such as a mobile communication module, a WiFi module, a Bluetooth module, etc., or various wired communication modules.

At least some of the components of the electronic device ED described above may be included in the display apparatus 1 according to the embodiments described above. Also, some of separate modules functionally included in one module may be included in the display apparatus 1 and the others may be provided separately from the display apparatus 1. For example, the display apparatus 1 may include the display module 2, and the processor 3, the memory 4, and the power module 5 may be provided in the electronic device ED, rather than the display apparatus 1, as other devices. As another example, the power module 5 may be provided in the display apparatus 1 and may provide a power supply to the processor 3 and the memory 4 which are provided in the electronic device ED, rather than the display apparatus 1. However, the disclosure is not limited thereto.

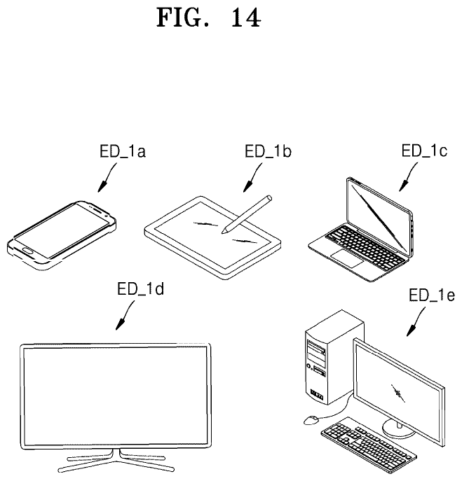

FIGS. 14 to 16 are schematic views of electronic devices according to various embodiments. FIGS. 14 to 16 illustrate examples of various electronic devices in which the display apparatus 1 according to embodiments is included.

FIG. 14 illustrates a smartphone ED_1a, a tablet PC ED_1b, a laptop computer ED_1c, a TV ED_1d, and a monitor ED_1e for a desk computer, as examples of the electronic devices.

The smartphone ED_1a may include an input module, such as a touch sensor, etc., and a communication module, in addition to the display module 2. The smartphone ED_1a may process information received through the communication module or other input modules and display the processed information through a display module of the display apparatus 1.

The tablet PC ED_1b, the laptop computer ED_1c, the TV ED_1d, and the monitor ED_1e for a desk computer may also include a display module and an input module, similarly as the smartphone ED_1a, and may further include a communication module according to cases.

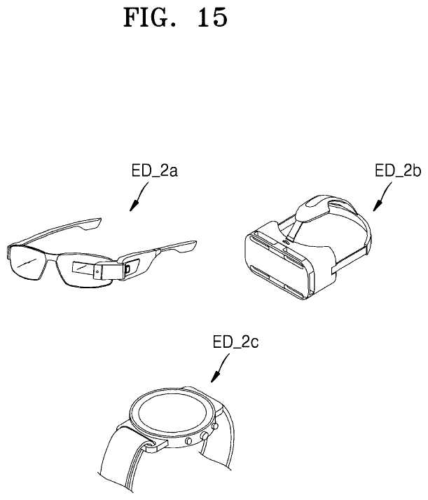

FIG. 15 illustrates a case where the electronic device ED including the display module 2 includes a wearable electronic device. The wearable electronic device may include smart glasses ED_2a, an HMD ED_2b, a smart watch ED_2c, etc.

The smart glasses ED_2a and the HMD ED_2b may include a display module configured to project a display image and a reflector configured to reflect the projected display screen and provide the display screen to a user's eye, so as to provide a screen of virtual reality (VR) or augmented reality (AR) to the user.

The smart watch ED_2c may include a biometric sensor as an input device and may provide biometric information recognized through the biometric sensor to the user through a display module.

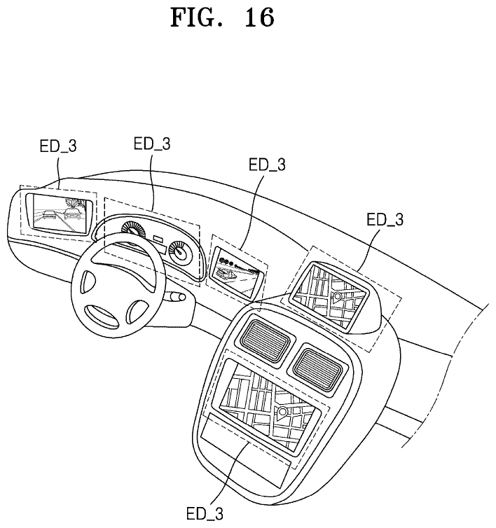

FIG. 16 illustrates a case where the electronic device ED including the display module 2 is included in a vehicle. For example, an electronic device ED_3 may be used in an instrument panel or a center fascia of the vehicle, or may be used as a CID arranged on a dashboard of the vehicle, or a room mirror display substituting a side-view mirror.

Although not shown, the electronic device in which the display apparatus 1 according to embodiments is included, may include not only devices mainly including a screen display, such as an advertisement board, an electronic display board, a game machine, etc., but also various home appliances for displaying information through a display module, such as a refrigerator, a laundry machine, a dryer, an air conditioner, a robot cleaner, etc. Also, when the display module has a light-transmission function, the electronic device may include a smart window or a transparent display apparatus for displaying the background and a display image together. Types of the electronic device according to an embodiment are not limited to the examples described above, and various other electronic devices may also be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A display apparatus comprising:
a display panel including a first surface including a display area, and a second surface different from the first surface;
a protective member disposed on the second surface and directly contacting the display panel;
a display controller including at least a portion of the display controller inserted into the protective member; and
a connection member electrically connecting the display panel to the display controller.

2. The display apparatus of claim 1, wherein the protective member comprises:
an embossed first layer;
a porous second layer disposed on the embossed first layer; and
a third layer including metal and disposed on the porous second layer.

3. The display apparatus of claim 2, wherein at least a portion of the display controller is disposed inside of the porous second layer.

4. The display apparatus of claim 2, wherein
the porous second layer includes an opening into which the display controller is received, and
a roughness of the opening is different from a roughness of another portion of the porous second layer.

5. The display apparatus of claim 1, further comprising:
an inner housing disposed on a lateral surface of the display panel and surrounding the display controller.

6. The display apparatus of claim 5, wherein the inner housing electrically connects the display controller to the protective member.

7. The display apparatus of claim 1, further comprising:
an adhesive member disposed between the protective member and the display controller.

8. The display apparatus of claim 1, wherein the connection member bends.

9. The display apparatus of claim 1, wherein
the protective member includes a first alignment mark in a portion on which the display controller is disposed, and
the display controller includes a second alignment mark in a position corresponding to the first alignment mark.

10. A display apparatus comprising:
a display panel including a first surface including a display area, and a second surface different from the first surface;
a display controller facing the second surface;
a protective member disposed between the second surface and the display controller, wherein
a thickness of a portion of the protective member where the display controller is disposed is different from a thickness of other portions of the protective member; and
a connection member electrically connecting the display panel to the display controller.

11. The display apparatus of claim 10, wherein the thickness of the portion of the protective member where the display controller is disposed is less than the thickness of the other portions of the protective member.

12. The display apparatus of claim 10, wherein the protective member comprises:
a first layer contacting the second surface of the display panel;
a second layer disposed on the first layer and including a first portion and a second portion having different thicknesses; and
a third layer including metal and disposed on the second layer.

13. The display apparatus of claim 12, wherein a roughness of a surface of the first portion facing the third layer including the metal is different from a roughness of a surface of the second portion.

14. The display apparatus of claim 12, wherein the third layer including the metal is electrically connected to the display controller.

15. The display apparatus of claim 10, further comprising:
an adhesive member disposed between the protective member and the display controller.

16. The display apparatus of claim 10, wherein
the protective member includes a first alignment mark in a portion on which the display controller is disposed, and
the display controller includes a second alignment mark in a position corresponding to the first alignment mark.

17. An electronic device comprising:
a display panel including a first surface including a display area, and a second surface different from the first surface;
a protective member disposed on the second surface of the display panel and directly contacting the display panel;
a display controller including at least a portion of the display controller inserted into the protective member; and
a connection member electrically connecting the display panel to the display controller.

18. The electronic device of claim 17, wherein the protective member comprises:
an embossed first layer;
a porous second layer disposed on the embossed first layer; and
a third layer including metal and disposed on the porous second layer.

19. The electronic device of claim 17, wherein
the protective member includes a first alignment mark in a portion on which the display controller is disposed, and
the display controller includes a second alignment mark in a position corresponding to the first alignment mark.

20. The electronic device of claim 17, wherein the electronic device is at least one of televisions, notebook computers, monitors, advertisement boards, Internet of things (IoTs) device, portable electronic devices including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.
